(19) United States
(12) Patent Application Publication
(10) Pub. No.: US 2007/0005519 A1
(43) Pub. Date: Jan. 4, 2007

(54) Systems and methods for utility meter demand data collection

(76) Inventor: Ravi Gupta, Alpharetta, GA (US)

Correspondence Address: JOHN S. PRATT, ESQ;KILPATRICK STOCKTON, LLP, 1100 PEACHTREE STREET, ATLANTA, GA, 30309, US

(21) Appl. No.: 11/157,097

(22) Filed: Jun. 20, 2005

(51) Int. Cl. G01R 21/133

(52) U.S. Cl. 705/412

(57) ABSTRACT

Systems and methods for utility meter data collection on distributed metering systems. One aspect of the present invention provides a method and system of remotely determining the highest demand peak occurring during a given billing cycle.

### FIELD OF THE INVENTION

The invention generally relates to systems and methods for utility meter data collection. More specifically, the invention relates to demand data collection and related calculations.

### BACKGROUND OF THE INVENTION

Commodities such as gas, electricity, and water are provided by utility companies around the world to households, businesses, and other consumers. Utility companies charge consumers in a variety of different ways. In many cases, utilities bill consumers based on the total cumulative amount of the commodity consumed during the billing period. However, in the electrical utility industry the desire to reduce costs by encouraging consumers to spread out or shift energy consumption has prompted the introduction of new types of billing schemes. For example, in many cases, the amount the consumer is billed depends on demand metering, time of use, and/or load profile information. Time of use and load profile schemes typically charge the consumer at different rates depending on the time of day that the energy is consumed by the consumer. For example, energy consumed in the morning may be more expensive then energy consumed in the middle of the night. Generally, time of use schemes involve larger blocks of time (e.g., morning, midday, evening, or late night) than load profile (e.g., dividing a day into 96 periods).

Demand metering, in the electric utility context, typically involves adding a premium to the consumer's bill based on the maximum amount of energy used in a small segment of the billing period. For example, such as scheme might look at the maximum amount of energy used in any fifteen-minute segment or increment during the billing period. Thus, the term demand, or demand peak, typically refers to the maximum rate of usage of energy, and more commonly, refers to the maximum usage within any 15-minute segment in a billing cycle. The segments may be non-overlapping (referred to as block demand) or overlapping (referred to as rolling demand). A daily demand peak is the demand peak that occurs in a given 24-hour period according to the meter clock. Demand reset refers to the process of initializing the demand to zero. In traditional, manually read meters, the demand reset occurs at the time of taking the reading. The terms billing cycle and billing period typically refer to the number of days reflected in each bill. Utility companies typically have varying number of days in each billing cycle.

Electric utility companies commonly gauge consumption, time-of-use, load profile, and demand using meters or meter attachment modules, to collect this information, and bill their customers accordingly. Traditionally, at the end of a reporting period, or billing cycle, a utility employee would physically inspect and record each customer's meter readout dials, which reflect usage. In a typical billing schedule, the utility company has a billing window surrounding the billing date during which the meters are read. This window is usually a period of 2-3 days around the billing date. For example, a “plus 1 minus 2” scheme refers to a billing window of two days before and one day after the billing date.

Many utility companies have deployed automatic meter reading systems that can automatically capture consumption data from the field. In many cases, adapter modules are fitted to existing meters to provide remote data collection capability. The modules typically collect the data and transmit it so that the data is ultimately received by the utility company. The data may be received by a data collection system at a remote location or by a moving data collection device, such as a van. Such drive-by data collection typically involves having the van or other moving data collection vehicle drive by and remotely collect the data from the metering device during the billing window.

Demand billing is a common practice in the electric utility industry. However, current techniques of capturing demand peak data in a drive-by environment have failed to adequately address the issue of resetting demand at the end of each billing cycle, often requiring expensive manual labor and/or more expensive two-way communicating devices. For example, in many cases, utilities are forced to reset demand through hard-wired connections. This translates to more time spent by utility personnel in the field. In other cases, meter readers reset demand remotely through a two-way communication device. Two-way communication devices are relatively more expensive compared to one-way communication devices. Some utilities have resorted to driving operating expenses down by downloading a billing calendar in the meter. However, this approach also has problems. For example, in addition to the difficulty of knowing the schedule in advance, utilities lose flexibility because they are tied to a predetermined calendar. In addition, changes to a billing calendar may require an expensive calendar update in the meters at all of the sites.

### SUMMARY OF THE INVENTION

The present invention comprises various systems and methods for utility meter data collection on distributed metering systems, such as that shown in U.S. Pat. Nos. 6,628,699; 5,918,380; 5,495,239; 4,799,059; and 4,654,662 (the disclosure of which are all incorporated herein by reference). Many of the embodiments of the present invention avoid many of the problems of prior art demand metering techniques.

One aspect of the present invention is a method of collecting utility demand data from a utility meter. This method includes determining a period of a set number of time intervals, wherein the period's length is equal to a maximum number of time intervals in any billing cycle plus a number of time intervals of slack. The method also determines a peak transmission count of a set number of time intervals, wherein the peak transmission count is equal to the maximum number of time intervals in any billing cycle minus the minimum number of time intervals in the billing cycle plus the number of time intervals of slack plus one. The method involves recording a demand peak at the passage of each time interval, wherein the demand peak is associated with the time interval in which it occurred. The method involves determining demand peak high values, wherein the demand peak high values are the highest demand peaks occurring over the last period, and the number of demand peak high values determined is equal to the peak transmission count. Demand peak high values are transmitted to a remote data collection system and the highest demand peak to occur during a billing period is determined from the demand peak high values. The “plus one” ensures that at least one value of the demand values that are transmitted will be within the billing period.

Another aspect of the present invention includes a utility demand data collection system having a utility meter reading device and a data collection device. The utility meter reading device is for determining a period and a peak transmission count, recording demand peaks and their associated time intervals, and determining demand peak high values, wherein the demand peak high values are the highest demand peaks occurring over the last period, and the number of demand peak high values is equal to the peak transmission count, and transmitting demand peak high values. The collection device is for receiving the transmitted demand peak high values and determining the highest demand peak to occur during a billing period.

### BRIEF DESCRIPTION OF THE DRAWINGS

These and other features, aspects, and advantages of the present invention are better understood when the following Detailed Description is read with reference to the accompanying drawings, wherein:

FIG. 1 illustrates a utility meter monitoring system in which the present invention may be utilized; and

FIG. 2 illustrates two billing cycles of differing lengths.

### DETAILED DESCRIPTION OF SPECIFIC EMBODIMENTS

Introduction

The present invention provides systems and methods for utility meter demand data collection. One aspect of the present invention provides a method and system of remotely determining the highest demand peak occurring during a given billing cycle. In this regard, the invention can capture the highest daily demand peaks for a given number of days (e.g., the highest 7 days) during a rolling period (e.g., 35 days). The number of highest demand peaks and the length of the rolling period allow for the calculation of the highest daily demand peak occurring during a billing period. Many different variations of this exemplary description are of course possible.

System Overview

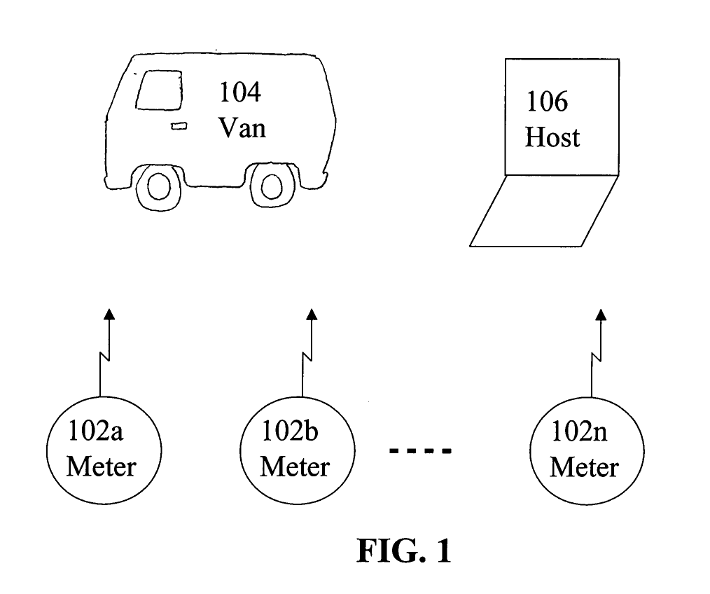

FIG. 1 illustrates a simplistic utility meter monitoring system in which the present invention may be utilized. The present invention is illustrated simplistically herein for ease of understanding. Of course, it is specifically contemplated that the present invention can be used in a more complex meter reading system, such as those described in U.S. Pat. Nos. 6,628,699; 6,617,978; 6,424,270; and 6,195,018, the disclosures of which are all incorporated herein by reference. Data is collected from utility meters 102a-n and eventually stored and used at host 106. The host 106 will typically use the usage data to generate statistics and consumer bills. A van 104, or other mobile data collection device, can be used to collect consumption and/or demand data from the meters 102a-n. The van 104 will typically be equipped with receiving equipment to receive wireless signals sent by the meters 102a-n. The information can be transferred from the mobile data collecting device 104 to the host system 106 in any suitable manner known in the art. A demand capturing subroutine in the host system can be used to tally demand peaks within a billing cycle and find the highest peak that falls within the billing cycle. This can be used as the demand for that billing cycle, to be used for billing purposes by the utility.

Determination of Variables

In one embodiment of the present invention, the system and method ensure that at least one of the demand peaks that are transmitted to the mobile data collection device 104 is the highest demand peak that falls within the billing period. In some embodiments, this is accomplished through the selection and use of several variables. The first variable, referred to as P or the peak transmission count, is the number of daily demand peaks that will be transmitted. In the examples presented herein, a daily time interval is used. Other embodiments use different time intervals, such as a half day. Moreover, the term daily can mean a calendar day or any other 24-hour period tracked by the metering device. The time interval is divided into segments and the demand peak is the segment occurring during the time interval that has the greatest amount of utility consumed. The demand peak, in certain embodiments refers to the maximum usage within a 15-minute segment occurring during the day. The segments may be non-overlapping (referred to as block demand) or overlapping (referred to as rolling demand).

The variable P, or peak transmission count, can be calculated as the maximum number of days in any billing cycle minus the minimum number of days in any billing cycle plus the number of days of slack in reading the meter plus 1. The number of days of slack in reading a meter refers to the number of days of flexibility provided in excess of the billing window. The slack value will have different values in different conditions. Generally, the slack value will be equal to the number of time intervals of flexibility in excess of a billing window. In an exemplary system where the maximum number of days in any billing cycle is 32, the minimum number of days in any billing cycle is 29, and the slack value is set to 3, the value of P, or the peak transmission count, will be 7=(32−29+3+1).

A second variable, N, or period, can also be useful in ensuring that at least one of the demand peaks that is transmitted to the mobile data collection device 104 is the highest demand peak that falls within the billing period. The variable N, or period, is the number of days of demand peaks that the highest demand values will later be selected from. In some embodiments, this value represents the length of the rolling history of demand peaks that are stored at the meter. The value of N, or period, is the maximum number of days in any billing cycle plus the number of days of slack in reading the meter. In the above example, where the maximum number of days in any billing cycle is 32, the minimum number of days in any billing cycle is 29, and the slack value is set to 3, the value of N, or the period, will be 35=(32+3).

Demand Peak Storage at the Meter or Module

In some embodiments, the meter, or module at the meter, will hold or store in memory daily demand peaks for the last N, or period, days. Demand peaks are only stored for intervals in the last period. The meter or module will progressively drop off old daily demand peaks as new daily demand peaks are recorded. Thus, in some embodiments a history of the last N, for example 35, demand peaks will be stored at the meter. In other embodiments, the meter or module will store more that N number of daily demand peaks but will use the variables at the time of transmission to ensure that at least one of the demand peaks that is transmitted to the mobile data collection device 104 is the highest demand peak that falls within the billing period.

Daily demand peaks stored at the meter or module are associated with the time increment, for example, the day in which they occur. Thus, the following chart illustrates the type of data that is stored in the example where N equals 35.

TABLE 1

| Day | Demand Peak |
|---|---|
| 1 | 2 |
| 2 | 4 |
| 3 | 3 |
| 4 | 4 |
| 5 | 2 |
| 6 | 6 |
| 7 | 3 |
| 8 | 5 |
| 9 | 2 |
| 10 | 1 |
| 11 | 1 |
| 12 | 1 |
| 13 | 1 |
| 14 | 1 |
| 15 | 1 |
| 16 | 9 |
| 17 | 2 |
| 18 | 3 |
| 19 | 1 |
| 20 | 2 |
| 21 | 1 |
| 22 | 4 |
| 23 | 6 |
| 24 | 4 |
| 25 | 4 |
| 26 | 3 |
| 27 | 2 |
| 28 | 4 |
| 29 | 4 |
| 30 | 8 |
| 31 | 1 |
| 32 | 3 |
| 33 | 2 |
| 34 | 10 |
| 35 | 3 |

The 35 daily demand peaks shown in Table 1 illustrate the daily demand peaks for the most recent 35 days. In this example, the newest entry appears at day 1 and the oldest daily demand entry appears at day 35. As the next daily demand peak is recorded, it is stored and the oldest entry will be dropped off. This is shown below in Table 2.

TABLE 2

| Day | Demand Peak |
|---|---|
| 1 | 5 |
| 2 | 2 |
| 3 | 4 |
| 4 | 3 |
| 5 | 4 |
| 6 | 2 |
| 7 | 6 |
| 8 | 3 |
| 9 | 5 |
| 10 | 2 |
| 11 | 1 |
| 12 | 1 |
| 13 | 1 |
| 14 | 1 |
| 15 | 1 |
| 16 | 1 |
| 17 | 9 |
| 18 | 2 |
| 19 | 3 |
| 20 | 1 |
| 21 | 2 |
| 22 | 1 |
| 23 | 4 |
| 24 | 6 |
| 25 | 4 |
| 26 | 4 |
| 27 | 3 |
| 28 | 2 |
| 29 | 4 |
| 30 | 4 |
| 31 | 8 |
| 32 | 1 |
| 33 | 3 |
| 34 | 2 |
| 35 | 10 |

The new value of “5” is stored at day 1, the middle values are each shifted down one position, and the prior value formerly associated with day 35 is dropped. Many other schemes and metehods of storing the daily demand peaks associated with their relative daily positions are of course possible. For example, the demand peaks can be stored and associated with an actual date value or with a days-since-occurrence value. As another example, each demand peak can be associated with a number, where higher numbers represent more recent data. In yet another example, a time stamp can be used with each daily peak enabling registration of the exact time the peak occurred. Any suitable scheme of storing daily demand data with data that allows the distinction between older and newer daily demand values can be used.

Transmission of Demand Peak Data

At transmission time, the meter or module will transmit only the highest demand peaks. Specifically, the meter, or module, will transmit the highest P, for example 7, demand peaks in memory. In the example shown in Table 2 above, this corresponds to the 7 highest daily demand peaks occurring over the last 35 days. These values are shown in Table 3 below:

TABLE 3

| Day | Demand Peak |
|---|---|
| 1 | 5 |
| 7 | 6 |
| 9 | 5 |
| 17 | 9 |
| 24 | 6 |
| 31 | 8 |
| 35 | 10 |

In the event of a tie, the oldest peak can be chosen for the transmission. This will avoid rewriting of module memory again and again for a zero usage account. This same rule can be applied to intra-day peaks.

In certain embodiments, a remote data collection system utilizes a drive-by collection device to receive the transmitted demand peak high values. In certain other embodiments, the remote data collection system utilizes a stationary data collection device.

Calculation of Demand

The demand peak information can be transferred from the mobile data collecting device 104 to the host system 106. Host system 106 can use the data to and peak during the appropriate billing period. For example, given the deman peak data from from Table 3 above, a billing cycle from March 15 to Apr. 12, 2005 (a 29 day period) and a collection day of Apr. 14, 2005, the highest demand peak falling within the period can be determined. One method is to work backwards from the collection day to determine the actual dates that the demand peaks reported occurred.

TABLE 4

| Day | Demand Peak | Date | Within Cycle |
|---|---|---|---|
| Collection Day | — | Apr. 14, 2005 | — |
| 1 | 5 | Apr. 13, 2005 | No |
| 7 | 6 | Apr. 7, 2005 | Yes |
| 9 | 5 | Apr. 5, 2005 | Yes |
| 17 | 9 | Mar. 28, 2005 | Yes |
| 24 | 6 | Mar. 21, 2005 | Yes |
| 31 | 8 | Mar. 14, 2005 | No |
| 35 | 10 | Mar. 10, 2005 | No |

in certain embodiments, determining the highest demand peak to occur during a billing period involves determining which of the demand peak high values occur within the billing period by determining whether the time interval associated with each demand peak high value occurs within the billing period. Accordingly, it is possible to determine which of the demand peak values correspond to dates within the applicable billing cycle as shown in Table 4 above. From these values, the applicable demand is selected. In this case, the highest demand peak within the billing cycle is 9 from day 17, which occurred on Mar. 28, 2005. The value of 10 on day 35 on Mar. 10, 2005 is rejected because it falls outside of the applicable billing cycle.

Ensuring that the Applicable Demand is Transmitted

As described above, the period and peak transmission count variables are selected to ensure that at least one demand peak that is transmitted to the mobile data collection device 104 is the highest demand peak that falls within the billing period. The period variable ensures that at least the minimum number of daily demand peaks are stored at the meter or module and the peak transmission count ensures that at least the minimum necessary number of demand peaks are transmitted. The selection of these variables takes account of the variance in billing cycle length and the slack value.

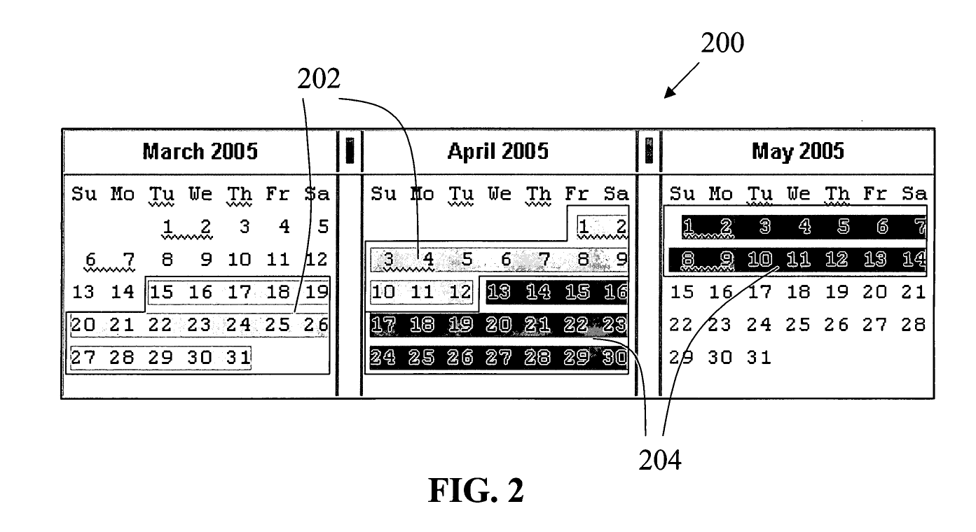

Referring now to FIG. 2, a calendar 200 is shown having a first billing cycle 202 and a second billing cycle 204. The first billing cycle 202 covers a period of only 29 days from March 15 through April 12. The second billing cycle 204 covers a period of 32 days from April 13 through May 14. These billing cycles 202, 204 represent the minimum and maximum number of days in any billing cycle respectively, in this example. Thus, as in the examples above, if slack is set at a value of 3 days, the period N will be 35 and the peak transmission count P will be 7.

For the first billing cycle 202, the mobile collector 104 reads from the meter or module may be taken between April 13 and April 15. If the mobile collector 104 reads on April 13, the demand peaks will range over the last 35 days

Now assume the mobile collector 104 reads are taken on April 15. The demand peaks collected over the last 35 days will represent the period from March 11 to Apr. 14, 2005.

For the second billing cycle 204, the mobile collector 104 reads from the meter or module 102a-n may be taken between May 15 and May 17. If the mobile reader collects data on May 15, the demand peaks collected will account for the prior 35 days, April 10 through May 14, 2005. Only three of the days in the 35-day period (April 10, 11, 12) may fall outside of the 32 day billing cycle. Accordingly, at least one of the seven daily demands transmitted will have occurred during the billing cycle.

Now assume the mobile collector 104 reads are taken on May 17. The demand peaks collected over the last 35 days will represent the period from April 12 to May 16, 2005. Only three of the days in the 35-day period (April 12 and May 15 and 16) may fall outside of the 32 day billing cycle. Accordingly, at least one of the seven daily demands transmitted will have occurred during the billing cycle.

These examples illustrate that even at the endpoint situations at least one of the seven daily demands transmitted will have occurred during the billing cycle. This ensures that it will always be possible to calculate the demand for the billing period given the information transmitted.

Alternative Embodiments

The structures and processes described above illustrate exemplary embodiments of inventive concepts included in the present invention. Other systems and processes are possible. While the invention has been described in detail with particular references to these particular embodiments, variations and modifications can be affected within the spirit and scope of the invention as described in this document. For example, the techniques of the present invention may also be used with a stationary data collection device rather than a mobile data collection device. Such an embodiment and other embodiments may use a slack value of zero. Nothing in this specification is meant to limit, expressly or implicitly, the plain meaning of the terms used in the following claims.

That which is claimed:

1. A method of collecting utility demand data from a utility meter comprising:
determining a period of a set number of time intervals, wherein the period's length is equal to a maximum number of time intervals in any billing cycle plus a number of time intervals of slack;
determining a peak transmission count of a set number of time intervals, wherein the peak transmission count is equal to the maximum number of time intervals in any billing cycle minus the minimum number of time intervals in the billing cycle plus the number of time intervals of slack plus one;
recording a demand peak at the passage of each time interval, wherein the demand peak is associated with the time interval in which it occurred;
determining demand peak high values, wherein the demand peak high values are the highest demand peaks occurring over the last period, and the number of demand peak high values determined is equal to the peak transmission count;
transmitting demand peak high values to a remote data collection system; and
determining the highest demand peak to occur during a billing period from the demand peak high values.

2. The method of claim 1 wherein the time interval is a day.

3. The method of claiml wherein the time interval is a half-day.

4. The method of claim 1 wherein the number of time intervals of slack is equal to the number of time intervals of flexibility in excess of a billing window.

5. The method of claim 1 wherein the time interval is divided into non-overlapping 15 minute segments and the demand peak is the 15 minute segment occurring during the time interval that has the greatest amount of utility consumed.

6. The method of claim 1 wherein the time interval is divided into overlapping 15 minute segments and the demand peak is the 15 minute segment occurring during the time interval that has the greatest amount of utility consumed.

7. The method of claim 1 wherein the time interval is divided into rolling 15 minute segments and the demand peak is the 15 minute segment occurring during the time interval that has the greatest amount of utility consumed.

8. The method of claim 1 further comprising storing demand peaks for only the intervals in the last period.

9. The method of claim 1 wherein the remote data collection system utilizes a drive-by data collection device to receive the transmitted demand peak high values.

10. The method of claim 1 wherein the remote data collection system utilizes a stationary data collection device to receive the transmitted demand peak high values.

11. The method of claim 1 wherein determining the highest demand peak to occur during a billing period further comprises determining which of the demand peak high values occur within the billing period by determining whether the time interval associated with each demand peak high value occurs within the billing period.

12. A utility demand data collection system comprising:
a utility meter reading device for determining a period and a peak transmission count, recording demand peaks and their associated time intervals, and determining demand peak high values, wherein the demand peak high values are the highest demand peaks occurring over the last period, and the number of demand peak high values is equal to the peak transmission count, and transmitting demand peak high values; and
a data collection device for receiving the transmitted demand peak high values and determining the highest demand peak to occur during a billing period.

13. The system of claim 12 wherein the time interval is a day.

14. The system of claim 12 wherein the number of time intervals of slack is equal to the number of time intervals of flexibility in excess of a billing window.

15. The system of claim 12 wherein the time interval is divided into non-overlapping 15 minute segments and the demand peak is the 15 minute segment occurring during the time interval that has the greatest amount of utility consumed.

16. The system of claim 12 wherein the time interval is divided into overlapping 15 minute segments and the demand peak is the 15 minute segment occurring during the time interval that has the greatest amount of utility consumed.

17. The system of claim 12 wherein the time interval is divided into rolling 15 minute segments and the demand peak is the 15 minute segment occurring during the time interval that has the greatest amount of utility consumed.

18. The system of claim 13 wherein a drive-by data collection device is used to receive the transmitted demand peak high values.

19. The system of claim 13 wherein a stationary data collection device is used to receive the transmitted demand peak high values.
